(19) United States
(12) Patent Application Publication
(10) Pub. No.: US 2020/0357924 A1
(43) Pub. Date: Nov. 12, 2020

(54) OXIDE SEMICONDUCTOR THIN FILM

(71) Applicant: ULVAC, INC., Chigasaki-shi, Kanagawa (JP)

(72) Inventors: Fumito OOTAKE, Chigasaki-shi, Kanagawa (JP); Motoshi KOBAYASHI, Chigasaki-shi, Kanagawa (JP); Mitsuru UENO, Chigasaki-shi, Kanagawa (JP); Masaru WADA, Chigasaki-shi, Kanagawa (JP); Kouichi MATSUMOTO, Chigasaki-shi, Kanagawa (JP)

(21) Appl. No.: 16/761,101

(22) PCT Filed: Nov. 19, 2018
(86) PCT No.: PCT/JP2018/042698

§ 371 Date: May 1, 2020

(30) Foreign Application Priority Data
Nov. 20, 2017 (JP) 2017-222524

(51) Int. Cl. H01L 29/786; H01L 29/66; C23C 14/08; C23C 14/34

(52) U.S. Cl. CPC H01L 29/7869; H01L 29/78618; C23C 14/3407; C23C 14/086; H01L 29/66742

(57) ABSTRACT

An oxide semiconductor thin film according to an embodiment of the present invention includes: an oxide semiconductor containing In, Zn, Ti, and Sn, an atomic ratio of (In+Sn)/(In+Zn+Ti+Sn) being not less than 0.36 and not more than 0.92, an atomic ratio of Sn/(In+Sn) being not less than 0.02 and not more than 0.46, an atomic ratio of Sn/(In+Zn+Ti+Sn) being not less than 0.01 and not more than 0.42, an atomic ratio of Ti/(In+Zn+Ti+Sn) being not less than 0.01 and not more than 0.10.

### TECHNICAL FIELD

The present invention relates to an oxide semiconductor thin film containing In, Zn, Ti, and Sn.

### BACKGROUND ART

A thin film transistor (TFT) using an In—Ga—Zn—O oxide semiconductor film (IGZO) as an active layer can achieve a high mobility as compared with a TFT using an existing amorphous silicon film as an active layer. For this reason, in recent years, it is widely applied to various displays (see, for example, Patent Literatures 1 to 3).

For example, Patent Literature 1 discloses an organic EL display apparatus in which the active layer of a TFT driving an organic EL device includes an IGZO. Patent Literature 2 discloses a thin film transistor in which a channel layer (active layer) includes a-IGZO and a mobility is not less than 5 cm²/Vs. Further, Patent Literature 3 discloses a thin film transistor in which an active layer includes IGZO and an on/off current ratio is 5 digits or more.

### CITATION LIST

### Patent Literature

Patent Literature 1: Japanese Patent Application Laid-open No. 2009-31750

Patent Literature 2: Japanese Patent Application Laid-open No. 2011-216574

Patent Literature 3: WO2010/092810

### DISCLOSURE OF INVENTION

### Technical Problem

In recent years, the demand for higher resolution, lower power consumption, and higher frame rate in various displays has increased a demand for an oxide semiconductor exhibiting a higher mobility. However, in a thin film transistor using IGZO as an active layer, it is difficult to achieve a mobility value exceeding 10 cm²/Vs, and development of a material for a thin film transistor exhibiting a higher mobility is desired.

In view of the circumstances as described above, it is an object of the present invention to provide a thin film transistor having high characteristics, which replaces IGSO, and a method of producing the same, and an oxide semiconductor thin film used for an active layer.

### Solution to Problem

In order to achieve the above-mentioned object, an oxide semiconductor thin film according to an embodiment of the present invention includes an oxide semiconductor containing In, Zn, Ti, and Sn,

an atomic ratio of (In+Sn)/(In+Zn+Ti+Sn) being not less than 0.36 and not more than 0.92,

an atomic ratio of Sn/(In+Sn) being not less than 0.02 and not more than 0.46,

an atomic ratio of Sn/(In+Zn+Ti+Sn) being not less than 0.01 and not more than 0.42,

an atomic ratio of Ti/(In+Zn+Ti+Sn) being not less than 0.01 and not more than 0.10.

In the above-mentioned oxide semiconductor thin film,

the atomic ratio of (In+Sn)/(In+Zn+Ti+Sn) may be not less than 0.48 and not more than 0.72,

the atomic ratio of Sn/(In+Sn) may be not less than 0.03 and not more than 0.29,

the atomic ratio of Sn/(In+Zn+Ti+Sn) may be not less than 0.02 and not more than 0.21, and

the atomic ratio of Ti/(In+Zn+Ti+Sn) may be not less than 0.03 and not more than 0.10.

A thin film transistor according to an embodiment of the present invention includes an active layer that includes the oxide semiconductor thin film having the above-mentioned configuration.

As a result, it is possible to form a thin film transistor having a mobility of not less than 10 cm²/Vs.

Further, it is possible to obtain a thin film transistor in which an amount of change in threshold value before and after execution of a test in which a gate voltage of +30 V is applied at a temperature of 60° C. for 60 minutes is not less than 0 V and not more than 2 V.

Alternatively, it is possible to obtain a thin film transistor in which an amount of change in threshold value before and after execution of a test in which a gate voltage of −30 V is applied at a temperature of 60° C. for 60 minutes is not less than 0 V and not more than 2 V.

A method of producing a thin film transistor according to an embodiment of the present invention is a method of producing a thin film transistor that includes an active layer including the oxide semiconductor thin film having the above-mentioned configuration, the method including:

forming a gate insulation film on a gate electrode;

forming the active layer on the gate insulation film by a sputtering method;

forming a metal layer having the active layer as a base film; and

patterning the metal layer by a wet etching method to form a source electrode and a drain electrode.

Since the active layer includes an oxide semiconductor thin film containing Sn, and thus has excellent chemical resistance. Therefore, it is possible to pattern a source/drain electrode without forming an etching stopper for protecting the active layer from an etching solution.

### Advantageous Effects of Invention

As described above, in accordance with the present invention, it is possible to provide a thin film transistor having high characteristics, which replaces IGZO.

### BRIEF DESCRIPTION OF DRAWINGS

FIG. 1 is a schematic cross-sectional view showing a configuration of a thin film transistor according to an embodiment of the present invention.

FIG. 2 is a diagram describing an operation of the above-mentioned thin film transistor.

### MODE(S) FOR CARRYING OUT THE INVENTION

Hereinafter, an embodiment of the present invention will be described with reference to the drawings.

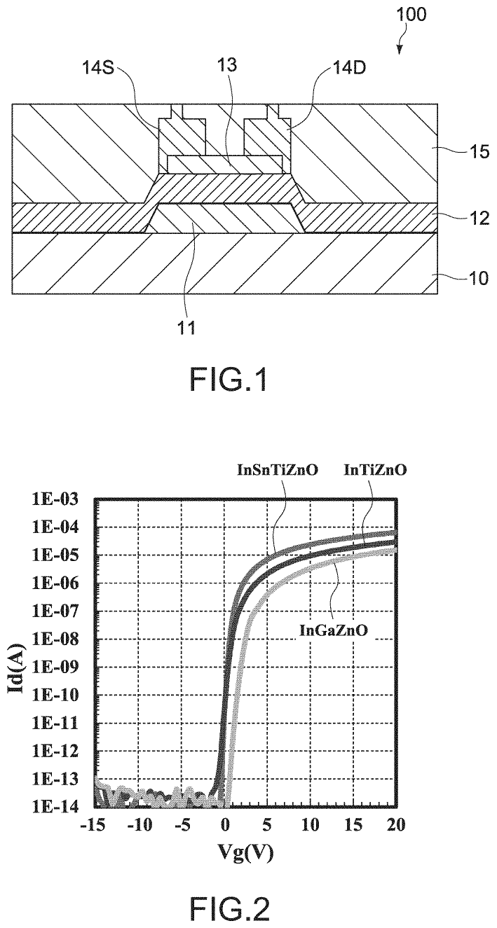

FIG. 1 is a schematic cross-sectional view showing a configuration of a thin film transistor according to an embodiment of the present invention. In this embodiment, a so-called bottom gate field effect transistor will be described as an example.

### [Thin Film Transistor]

A thin film transistor 100 according to this embodiment includes a gate electrode 11, a gate insulation film 12, an active layer 13, a source electrode 14S, and a drain electrode 14D.

The gate electrode 11 includes a conductive film formed on the surface of a substrate 10. The substrate 10 is typically a transparent glass substrate. The gate electrode 11 typically includes a metal single layer or metal multilayer of molybdenum (Mo), titanium (Ti), aluminum (Al), cupper (Cu), or the like, and is formed by, for example, a sputtering method. In this embodiment, the gate electrode 11 is formed of molybdenum. The thickness of the gate electrode 11 is not particularly limited, and is, for example, 200 nm. The gate electrode 11 is deposited by, for example, a sputtering method, a vacuum evaporation method, or the like.

The active layer 13 functions as a channel layer of the thin film transistor 100. The film thickness of the active layer 12 is, for example, 10 nm to 200 nm. The active layer 13 includes an In—Sn—Ti—Zn—O oxide semiconductor thin film containing In (indium), Zn (zinc), Ti (titanium), and Sn (tin). The active layer 13 is deposited by, for example, a sputtering method. The specific composition of the above-mentioned oxide semiconductor thin film will be described below.

The gate insulation film 12 is formed between the gate electrode 11 and the active layer 13. The gate insulation film 12 includes, for example, a silicon oxide film (SiOx), a silicon nitride film (SiNx), or a stacked film of these. The deposition method is not particularly limited, and a CVD method, a sputtering method, an evaporation method or the like may be used. The film thickness of the gate insulation film 12 is not particularly limited, and is, for example, 200 nm to 400 nm.

The source electrode 14S and the drain electrode 14D are formed on the active layer 13 to be separated from each other. The source electrode 14S and the drain electrode 14D can include, for example, a metal single layer of aluminum, molybdenum, copper, titanium, or the like, or a multilayer of these metals. As described below, the source electrode 14S and the drain electrode 14D can be simultaneously formed by patterning the metal film. The thickness of the metal film is, for example, 100 nm to 200 nm. The source electrode 14S and the drain electrode 14D are deposited by, for example, a sputtering method, a vacuum evaporation method, or the like.

The source electrode 14S and the drain electrode 14D are covered by a protective film 15. The protective film 15 is formed of an electrically insulating material such as a silicon oxide film, a silicon nitride film, and a stacked film of these. The protective film 15 is for shielding a device portion including the active layer 13 from the outside air. The film thickness of the protective film 15 is not particularly limited, and is, for example, 100 nm to 300 nm. The protective film 15 is deposited by, for example, a CVD method.

After forming the protective film 15, annealing treatment is performed. As a result, the active layer 13 is activated. The conditions of annealing are not particularly limited. In this embodiment, the annealing treatment is performed at 300° C. for 1 hour in the atmosphere.

In the protective film 15, interlayer connection holes for connecting the source/drain electrodes 14S and 14D to a wiring layer (illustration omitted) are provided at appropriate positions. The above-mentioned wiring layer is for connecting the thin film transistor 100 to a peripheral circuit (not shown), and includes a transparent conductive film such as ITO.

[Oxide Semiconductor Thin Film]

Subsequently, an oxide semiconductor thin film constituting the active layer 13 will be described.

The active layer 13 includes an oxide semiconductor thin film containing In, Zn, Ti, and Sn as described above.

The atomic ratio (atomic ratio of the sum of In and Sn to the total of In, Zn, Ti, and Sn) of (In+Sn)/(In+Zn+Ti+Sn) is not less than 0.36 and not more than 0.92.

The atomic ratio (atomic ratio of Sn to the sum of In and Sn) of Sn/(In+Sn) is not less than 0.02 and not more than 0.46.

The atomic ratio (atomic ratio of Sn to the total of In, Zn, Ti, and Sn) of Sn/(In+Zn+Ti+Sn) is not less than 0.01 and not more than 0.42.

The atomic ratio (atomic ratio of Ti to the total of In, Zn, Ti, and Sn) of Ti/(In+Zn+Ti+Sn) is not less than 0.01 and not more than 0.10.

Note that the upper limit value and lower limit value of the composition indicate values obtained by rounding off the third decimal place (the same applies hereinafter).

By forming the active layer 13 of In—Sn—Ti—Zn—O oxide semiconductor thin film in the above-mentioned composition range, transistor characteristics having a mobility of not less than 10 cm²/Vs can be achieved.

Further, in this embodiment, since the active layer 13 includes an oxide semiconductor thin film containing Sn, the active layer 13 having excellent chemical resistance can be formed. Therefore, in the process of patterning the source electrode 14S and the drain electrode 14D, it is unnecessary to provide an etching stopper layer for protecting the active layer from an etching solution. As a result, by forming a metal layer having the active layer 13 as a base film and then patterning the metal layer by a wet etching method, the source electrode 14S and the drain electrode 14D can be easily formed.

Examples of the etching solution typically include a PAN (Phosphoric Acetic Nitric acid) solution 1 (mixed solution of phosphoric acid≈75%, nitric acid≈10%, acetic acid≈14%, water≈1%), and a PAN solution 2 (mixed solution of phosphoric acid≈73%, nitric acid≈3%, acetic acid≈7%, water≈17%).

In the oxide semiconductor thin film constituting the active layer 13, it is favorable that the atomic ratio of (In+Sn)/(In+Zn+Ti+Sn) is not less than 0.48 and not more than 0.72, the atomic ratio of Sn/(In+Sn) is not less than 0.03 and not more than 0.29, the atomic ratio of Sn/(In+Zn+Ti+Sn) is not less than 0.02 and not more than 0.21, and the atomic ratio of Ti/(In+Zn+Ti+Sn) is not less than 0.03 and not more than 0.10.

As a result, transistor characteristics having a mobility of not less than 20 cm²/Vs can be achieved.

In accordance with the oxide semiconductor thin film in the above-mentioned composition range, the fluctuation of the threshold value voltage can be suppressed to a predetermined voltage. Therefore, it is possible to secure a highly reliable switching operation for a long time. For example, the present inventors have confirmed that favorable results can be achieved for both PBTS (Positive Bias Temperature Stress) and NBTS (Negative Bias Temperature Stress) in a BTS test in which a constant voltage is applied between the gate electrode-the source electrode (or between the gate electrode-the source electrode, and the drain electrode-the source electrode) of the thin film transistor to evaluate the fluctuation of the threshold value voltage at that time.

Specifically, the amount of change in threshold value voltage before and after the execution of the PBTS test in which a gate voltage of +30 V is applied at the temperature of 60° C. for 60 minutes was not less than 0 V and not more than 2 V.

Further, the amount of change in threshold value before and after the execution of the test in which a gate voltage of −30 V is applied at the temperature of 60° C. for 60 minutes was not less than −2 V and not more than 0 V.

The active layer 13 is formed by forming a film using a sputtering target including a sintered body of respective oxides of In, Zn, Ti, and Sn and then performing heat treatment (annealing) at a predetermined temperature. By sputtering the above-mentioned target at predetermined conditions, an oxide semiconductor thin film having the same or substantially the same composition as the composition of the target is formed. By performing annealing treatment on this semiconductor film at a predetermined temperature, an active layer that exhibits transistor characteristics having a mobility of not less than 10 cm²/Vs, for example, is formed.

The above-mentioned sputtering target can include a sintered body obtained by using respective oxides of In, Ti, Zn, and Sn, e.g., In₂O₃, TiO₂, ZnO, and SnO₂, as raw material powders, and mixing them at the above-mentioned composition ratio.

[Characteristics Evaluation]

As shown in FIG. 2, when the transfer characteristics of the thin film transistor using an In—Sn—Ti—Zn—SnO film as an active layer are evaluated, a mobility and an on/off current ratio are confirmed to be high as compared with those of the In—Ti—Zn—O oxide semiconductor thin film and In—Ga—Zn—O oxide thin film.

Here, the drain current (Id) when the gate voltage (Vg) was −15 V was regarded the off current, the drain current (Id) when the gate voltage (Vg) was +20 V was regarded the on current, and the ratio of the on current to the off current was regarded as the on/off current ratio.

Further, when the gate voltage (Vg) at which the drain current (Id) became 1E-09 (1.0×10⁻⁹) A was regarded as the threshold value voltage (Vth), it was confirmed that the threshold value voltage shifts to the + side (approximately 6 V at most) as the voltage application time was longer in the In—Ga—Zn—O oxide thin film while the shift amount was not more than 2 V in the In—Sn—Ti—Zn—O oxide thin film.

### Experimental Example

The present inventors formed an In—Ti—Zn—O oxide thin film, an In—Sn—Ti—Zn—O oxide thin film, and an In—Ga—Zn—O oxide semiconductor thin film by a sputtering method, and prepared thin film transistors each having the structure shown in FIG. 1 using these films as active layers to evaluate the transfer characteristics (a mobility, a threshold value voltage, PBTS, NBTS) of each transistor. Further, the film characteristics (a carrier density and a wet etching rate) of the above-mentioned oxide semiconductor thin film were evaluated.

As the threshold value voltage (Vth), the gate voltage (Vg) at which the drain current (Id) became 1.0×10⁻⁹ A was used.

As PBTS (ΔVth), the amount of change in threshold value after applying the gate voltage of +30 V at the temperature of 60° C. for 60 minutes was used.

As NBTS (ΔVth), the amount of change in threshold value after applying the gate voltage of −30 V at the temperature of 60° C. for 60 minutes was used.

As the carrier density, after annealing the oxide semiconductor thin film immediately after the deposition at 350° C. for one hour in the atmosphere, the carrier concentration in the film was measured using a Hall effect measuring device.

For the measurement of the etching rate, a Dip method in which the oxide semiconductor thin film immediately after the deposition was immersed in a chemical solution (phosphoric acetic nitric acid etching solution) controlled to be 40° C. was adopted.

Regarding the deposition conditions, the substrate temperature was 100° C., the sputtering gas was a mixed gas of argon and oxygen (oxygen content ratio of 7%), and the film thickness was 50 nm.

(Sample 1)

An In—Ti—Zn—O oxide semiconductor thin film in which the atomic ratio of each element to the total amount of In, Zn, and Ti satisfied the relationship of In:48 atomic %, Zn:48 atomic %, and Ti:4 atomic % was prepared on a glass substrate by using an In—Ti—Zn—O target.

As a result of evaluating the transfer characteristics of a thin film transistor that includes an active layer including the prepared oxide semiconductor thin film, the mobility was 12 cm²/Vs, the threshold value voltage (Vth) was 0.4 V, PBTS (Vth) was +3.2 V, and NBTS (Vth) was −0.1 V.

As a result of evaluating the film characteristics of the above-mentioned oxide semiconductor thin film, the carrier density was 5.1E+16 (5.1×10¹⁶)/cm³ and the etching rate was 4.7 nm/sec.

(Sample 2)

An In—Ti—Zn—O oxide semiconductor thin film in which the atomic ratio of each element to the total amount of In, Zn, and Ti satisfied the relationship of In:58 atomic %, Zn:38 atomic %, and Ti:4 atomic % was prepared on a glass substrate by using an In—Ti—Zn—O target.

As a result of evaluating the transfer characteristics of a thin film transistor that includes an active layer including the prepared oxide semiconductor thin film, the mobility was 15 cm²/Vs, the threshold value voltage (Vth) was 0.7 V, PBTS (Vth) was +1.8 V, and NBTS (Vth) was −1.2 V.

As a result of evaluating the film characteristics of the above-mentioned oxide semiconductor thin film, the carrier density was 2.5E+17 (2.5×10¹⁷)/cm³ and the etching rate was 2.8 nm/sec.

(Sample 3)

An In—Ti—Zn—O oxide semiconductor thin film in which the atomic ratio of each element to the total amount of In, Zn, and Ti satisfied the relationship of In:85 atomic %, Zn:7 atomic %, and Ti:8 atomic % was prepared on a glass substrate by using an In—Ti—Zn—O target.

As a result of evaluating the transfer characteristics of a thin film transistor that includes an active layer including the prepared oxide semiconductor thin film, the mobility was 50 cm²/Vs, the threshold value voltage (Vth) was −5.2 V, PBTS (Vth) was +0.5 V, and NBTS (Vth) was −5.0 V.

As a result of evaluating the film characteristics of the above-mentioned oxide semiconductor thin film, the carrier density was 4.1E+19 (4.1×10¹⁹)/cm³ and the etching rate was less than 0.1 nm/sec (measurement limitation).

(Sample 4)

An In—Ti—Zn—O oxide semiconductor thin film in which the atomic ratio of each element to the total amount of In, Zn, and Ti satisfied the relationship of In:38 atomic %, Zn:58 atomic %, and Ti:4 atomic % was prepared on a glass substrate by using an In—Ti—Zn—O target.

As a result of evaluating the transfer characteristics of a thin film transistor that includes an active layer including the prepared oxide semiconductor thin film, the mobility was 6 cm²/Vs, the threshold value voltage (Vth) was 0.3 V, PBTS (Vth) was +3.2 V, and NBTS (Vth) was −0.9 V.

As a result of evaluating the film characteristics of the above-mentioned oxide semiconductor thin film, the carrier density was 2.5E+16 (2.5×10¹⁶)/cm³ and the etching rate was 13.0 nm/sec.

(Sample 5)

An In—Ti—Zn—O oxide semiconductor thin film in which the atomic ratio of each element to the total amount of In, Zn, and Ti satisfied the relationship of In:17 atomic %, Zn:75 atomic %, and Ti:8 atomic % was prepared on a glass substrate by using an In—Ti—Zn—O target.

As a result of evaluating the transfer characteristics of a thin film transistor that includes an active layer including the prepared oxide semiconductor thin film, the mobility was 5 cm²/Vs, the threshold value voltage (Vth) was 2.8 V, PBTS (Vth) was +4.5 V, and NBTS (Vth) was −0.5 V.

As a result of evaluating the film characteristics of the above-mentioned oxide semiconductor thin film, the carrier density was 4.0E+14 (4.0×10¹⁴)/cm³ and the etching rate was 15.0 nm/sec.

(Sample 6)

An In—Sn—Ti—Zn—O oxide semiconductor thin film in which the atomic ratio of each element to the total amount of In, Zn, Ti, and Sn satisfied the relationship of In:35 atomic %, Zn:60 atomic %, Ti:4 atomic %, and Sn:1 atomic % was prepared on a glass substrate by using an In—Sn—Ti—Zn—O target.

As a result of evaluating the transfer characteristics of a thin film transistor that includes an active layer including the prepared oxide semiconductor thin film, the mobility was 10 cm²/Vs, the threshold value voltage (Vth) was 1.8 V, PBTS (Vth) was +1.8 V, and NBTS (Vth) was −0.4 V.

As a result of evaluating the film characteristics of the above-mentioned oxide semiconductor thin film, the carrier density was 3.5E+17 (3.5×10¹⁷)/cm³ and the etching rate was 10.0 nm/sec.

(Sample 7)

An In—Sn—Ti—Zn—O oxide semiconductor thin film in which the atomic ratio of each element to the total amount of In, Zn, Ti, and Sn satisfied the relationship of In:58 atomic %, Zn:37 atomic %, Ti:4 atomic %, and Sn:1 atomic % was prepared on a glass substrate by using an In—Sn—Ti—Zn—O target.

As a result of evaluating the transfer characteristics of a thin film transistor that includes an active layer including the prepared oxide semiconductor thin film, the mobility was 17 cm²/Vs, the threshold value voltage (Vth) was 0.7 V, PBTS (Vth) was +0.9 V, and NBTS (Vth) was −1.2 V.

As a result of evaluating the film characteristics of the above-mentioned oxide semiconductor thin film, the carrier density was 5.6E+17 (5.6×10¹⁷)/cm³ and the etching rate was 2.6 nm/sec.

(Sample 8)

An In—Sn—Ti—Zn—O oxide semiconductor thin film in which the atomic ratio of each element to the total amount of In, Zn, Ti, and Sn satisfied the relationship of In:46 atomic %, Zn:48 atomic %, Ti:4 atomic %, and Sn:2 atomic % was prepared on a glass substrate by using an In—Sn—Ti—Zn—O target.

As a result of evaluating the transfer characteristics of a thin film transistor that includes an active layer including the prepared oxide semiconductor thin film, the mobility was 20 cm²/Vs, the threshold value voltage (Vth) was 0.9 V, PBTS (Vth) was +1.5 V, and NBTS (Vth) was −0.6 V.

As a result of evaluating the film characteristics of the above-mentioned oxide semiconductor thin film, the carrier density was 4.2E+17 (4.2×10¹⁷)/cm³ and the etching rate was 3.0 nm/sec.

(Sample 9)

An In—Sn—Ti—Zn—O oxide semiconductor thin film in which the atomic ratio of each element to the total amount of In, Zn, Ti, and Sn satisfied the relationship of In:56 atomic %, Zn:39 atomic %, Ti:3 atomic %, and Sn:2 atomic % was prepared on a glass substrate by using an In—Sn—Ti—Zn—O target.

As a result of evaluating the transfer characteristics of a thin film transistor that includes an active layer including the prepared oxide semiconductor thin film, the mobility was 21 cm²/Vs, the threshold value voltage (Vth) was 0.8 V, PBTS (Vth) was +1.2 V, and NBTS (Vth) was −1.0 V.

As a result of evaluating the film characteristics of the above-mentioned oxide semiconductor thin film, the carrier density was 3.5E+17 (3.5×10¹⁷)/cm³ and the etching rate was 2.2 nm/sec.

(Sample 10)

An In—Sn—Ti—Zn—O oxide semiconductor thin film in which the atomic ratio of each element to the total amount of In, Zn, Ti, and Sn satisfied the relationship of In:57 atomic %, Zn:35 atomic %, Ti:3 atomic %, and Sn:5 atomic % was prepared on a glass substrate by using an In—Sn—Ti—Zn—O target.

As a result of evaluating the transfer characteristics of a thin film transistor that includes an active layer including the prepared oxide semiconductor thin film, the mobility was 23 cm²/Vs, the threshold value voltage (Vth) was 0.6 V, PBTS (Vth) was +1.0 V, and NBTS (Vth) was −0.7 V.

As a result of evaluating the film characteristics of the above-mentioned oxide semiconductor thin film, the carrier density was 5.6E+17 (5.6×10¹⁷)/cm³ and the etching rate was 1.0 nm/sec.

(Sample 11)

An In—Sn—Ti—Zn—O oxide semiconductor thin film in which the atomic ratio of each element to the total amount of In, Zn, Ti, and Sn satisfied the relationship of In:53 atomic %, Zn:30 atomic %, Ti:3 atomic %, and Sn:14 atomic % was prepared on a glass substrate by using an In—Sn—Ti—Zn—O target.

As a result of evaluating the transfer characteristics of a thin film transistor that includes an active layer including the prepared oxide semiconductor thin film, the mobility was 26 cm²/Vs, the threshold value voltage (Vth) was 0.3 V, PBTS (Vth) was +0.7 V, and NBTS (Vth) was −0.2 V.

As a result of evaluating the film characteristics of the above-mentioned oxide semiconductor thin film, the carrier density was 2.5E+18 (2.5×10¹⁸)/cm³ and the etching rate was less than 0.1 nm/sec (measurement limitation).

(Sample 12)

An In—Sn—Ti—Zn—O oxide semiconductor thin film in which the atomic ratio of each element to the total amount of In, Zn, Ti, and Sn satisfied the relationship of In:52 atomic %, Zn:28 atomic %, Ti:3 atomic %, and Sn:17 atomic % was prepared on a glass substrate by using an In—Sn—Ti—Zn—O target.

As a result of evaluating the transfer characteristics of a thin film transistor that includes an active layer including the prepared oxide semiconductor thin film, the mobility was 27 cm²/Vs, the threshold value voltage (Vth) was 0.2 V, PBTS (Vth) was +0.6 V, and NBTS (Vth) was −1.5 V.

As a result of evaluating the film characteristics of the above-mentioned oxide semiconductor thin film, the carrier density was 4.1E+18 (4.1×10¹⁸)/cm³ and the etching rate was less than 0.1 nm/sec (measurement limitation).

(Sample 13)

An In—Sn—Ti—Zn—O oxide semiconductor thin film in which the atomic ratio of each element to the total amount of In, Zn, Ti, and Sn satisfied the relationship of In:51 atomic %, Zn:25 atomic %, Ti:3 atomic %, and Sn:21 atomic % was prepared on a glass substrate by using an In—Sn—Ti—Zn—O target.

As a result of evaluating the transfer characteristics of a thin film transistor that includes an active layer including the prepared oxide semiconductor thin film, the mobility was 28 cm²/Vs, the threshold value voltage (Vth) was 0.1 V, PBTS (Vth) was +0.6 V, and NBTS (Vth) was −2.0 V.

As a result of evaluating the film characteristics of the above-mentioned oxide semiconductor thin film, the carrier density was 4.0E+18 (4.0×10¹⁸)/cm³ and the etching rate was less than 0.1 nm/sec (measurement limitation).

(Sample 14)

An In—Sn—Ti—Zn—O oxide semiconductor thin film in which the atomic ratio of each element to the total amount of In, Zn, Ti, and Sn satisfied the relationship of In:51 atomic %, Zn:18 atomic %, Ti:10 atomic %, and Sn:21 atomic % was prepared on a glass substrate by using an In—Sn—Ti—Zn—O target.

As a result of evaluating the transfer characteristics of a thin film transistor that includes an active layer including the prepared oxide semiconductor thin film, the mobility was 20 cm²/Vs, the threshold value voltage (Vth) was 0.7 V, PBTS (Vth) was +1.1 V, and NBTS (Vth) was −0.6 V.

As a result of evaluating the film characteristics of the above-mentioned oxide semiconductor thin film, the carrier density was 6.0E+17 (6.0×10¹⁷)/cm³ and the etching rate was less than 0.1 nm/sec (measurement limitation).

(Sample 15)

An In—Sn—Ti—Zn—O oxide semiconductor thin film in which the atomic ratio of each element to the total amount of In, Zn, Ti, and Sn satisfied the relationship of In:52 atomic %, Zn:5 atomic %, Ti:3 atomic %, and Sn:40 atomic % was prepared on a glass substrate by using an In—Sn—Ti—Zn—O target.

As a result of evaluating the transfer characteristics of a thin film transistor that includes an active layer including the prepared oxide semiconductor thin film, the mobility was 29 cm²/Vs, the threshold value voltage (Vth) was −3.6 V, PBTS (Vth) was +0.5 V, and NBTS (Vth) was −3.4 V.

As a result of evaluating the film characteristics of the above-mentioned oxide semiconductor thin film, the carrier density was 8.5E+18 (8.5×10¹⁸)/cm³ and the etching rate was less than 0.1 nm/sec (measurement limitation).

(Sample 16)

An In—Sn—Ti—Zn—O oxide semiconductor thin film in which the atomic ratio of each element to the total amount of In, Zn, Ti, and Sn satisfied the relationship of In:50 atomic %, Zn:4 atomic %, Ti:4 atomic %, and Sn:42 atomic % was prepared on a glass substrate by using an In—Sn—Ti—Zn—O target.

As a result of evaluating the transfer characteristics of a thin film transistor that includes an active layer including the prepared oxide semiconductor thin film, the mobility was 32 cm²/Vs, the threshold value voltage (Vth) was −4.6 V, PBTS (Vth) was +0.2 V, and NBTS (Vth) was −4.8 V.

As a result of evaluating the film characteristics of the above-mentioned oxide semiconductor thin film, the carrier density was 6.0E+19 (6.0×10¹⁹)/cm³ and the etching rate was less than 0.1 nm/sec (measurement limitation).

(Sample 17)

An In—Sn—Ti—Zn—O oxide semiconductor thin film in which the atomic ratio of each element to the total amount of In, Zn, Ti, and Sn satisfied the relationship of In:63 atomic %, Zn:19 atomic %, Ti:4 atomic %, and Sn:14 atomic % was prepared on a glass substrate by using an In—Sn—Ti—Zn—O target.

As a result of evaluating the transfer characteristics of a thin film transistor that includes an active layer including the prepared oxide semiconductor thin film, the mobility was 27 cm²/Vs, the threshold value voltage (Vth) was −0.8 V, PBTS (Vth) was +0.6 V, and NBTS (Vth) was −2.2 V.

As a result of evaluating the film characteristics of the above-mentioned oxide semiconductor thin film, the carrier density was 5.2E+18 (5.2×10¹⁸)/cm³ and the etching rate was less than 0.1 nm/sec (measurement limitation).

(Sample 18)

An In—Sn—Ti—Zn—O oxide semiconductor thin film in which the atomic ratio of each element to the total amount of In, Zn, Ti, and Sn satisfied the relationship of In:54 atomic %, Zn:32 atomic %, Ti:1 atomic %, and Sn:13 atomic % was prepared on a glass substrate by using an In—Sn—Ti—Zn—O target.

As a result of evaluating the transfer characteristics of a thin film transistor that includes an active layer including the prepared oxide semiconductor thin film, the mobility was 25 cm²/Vs, the threshold value voltage (Vth) was −4.1 V, PBTS (Vth) was +1.1 V, and NBTS (Vth) was −4.2 V.

As a result of evaluating the film characteristics of the above-mentioned oxide semiconductor thin film, the carrier density was 2.8E+19 (2.8×10¹⁹)/cm³ and the etching rate was less than 0.1 nm/sec (measurement limitation).

(Sample 19)

An In—Sn—Ti—Zn—O oxide semiconductor thin film in which the atomic ratio of each element to the total amount of In, Zn, Ti, and Sn satisfied the relationship of In:53 atomic %, Zn:30 atomic %, Ti:10 atomic %, and Sn:7 atomic % was prepared on a glass substrate by using an In—Sn—Ti—Zn—O target.

As a result of evaluating the transfer characteristics of a thin film transistor that includes an active layer including the prepared oxide semiconductor thin film, the mobility was 11 cm²/Vs, the threshold value voltage (Vth) was 2.6 V, PBTS (Vth) was +3.4 V, and NBTS (Vth) was −0.6 V.

As a result of evaluating the film characteristics of the above-mentioned oxide semiconductor thin film, the carrier density was 7.0E+16 (7.0×10¹⁶)/cm³ and the etching rate was less than 0.1 nm/sec (measurement limitation).

(Sample 20)

An In—Sn—Ti—Zn—O oxide semiconductor thin film in which the atomic ratio of each element to the total amount of In, Zn, Ti, and Sn satisfied the relationship of In:40 atomic %, Zn:38 atomic %, Ti:12 atomic %, and Sn:10 atomic % was prepared on a glass substrate by using an In—Sn—Ti—Zn—O target.

As a result of evaluating the transfer characteristics of a thin film transistor that includes an active layer including the prepared oxide semiconductor thin film, the mobility was 8 cm²/Vs, the threshold value voltage (Vth) was 2.8 V, PBTS (Vth) was +3.1 V, and NBTS (Vth) was −0.7 V.

As a result of evaluating the film characteristics of the above-mentioned oxide semiconductor thin film, the carrier density was 3.8E+15 (3.8×10¹⁶)/cm³ and the etching rate was less than 0.1 nm/sec (measurement limitation).

(Sample 21)

An In—Ga—Zn—O oxide semiconductor thin film in which the atomic ratio of each element to the total amount of In, Zn, and Ga satisfied the relationship of In:33 atomic %, Zn:33 atomic %, and Ga:33 atomic % was prepared on a glass substrate by using an In—Ga—Zn—O target.

As a result of evaluating the transfer characteristics of a thin film transistor that includes an active layer including the prepared oxide semiconductor thin film, the mobility was 8 cm²/Vs, the threshold value voltage (Vth) was 3.6 V, PBTS (Vth) was +6.3 V, and NBTS (Vth) was 0.2 V.

As a result of evaluating the film characteristics of the above-mentioned oxide semiconductor thin film, the carrier density was 5.7E+14 (5.7×10¹⁴)/cm³ and the etching rate was 5.3 nm/sec.

The atomic ratios 1 to 4 defined as follows for the samples 1 to 19 are shown in Table 1, and the evaluation results of the samples 1 to 19 are collectively shown in Table 2.

Atomic ratio 1: (In+Sn)/(In+Zn+Ti+Sn)

Atomic ratio 2: Sn/(In+Sn)

Atomic ratio 3: Sn/(In+Zn+Ti+Sn)

Atomic ratio 4: Ti/(In+Zn+Ti+Sn)

TABLE 1

| | | | | | | Atomic ratio 1 | Atomic ratio 2 | Atomic ratio 3 | Atomic ratio 4 |
|---|---|---|---|---|---|---|---|---|---|
| | Composition at % | | | | | In + Sn | Sn | Sn | Ti |
| No | In | Zn | Ti | Sn | Ga | In + Zn + Ti + Sn | In + Sn | In + Zn + Ti + Sn | In + Zn + Ti + Sn |
| 1 | 48 | 48 | 4 | — | — | 0.480 | 0.000 | 0.000 | 0.000 |
| 2 | 58 | 38 | 4 | — | — | 0.580 | 0.000 | 0.000 | 0.000 |
| 3 | 85 | 7 | 8 | — | — | 0.850 | 0.000 | 0.000 | 0.000 |
| 4 | 38 | 58 | 4 | — | — | 0.382 | 0.000 | 0.000 | 0.000 |
| 5 | 17 | 75 | 8 | — | — | 0.170 | 0.000 | 0.000 | 0.000 |
| 6 | 35 | 60 | 4 | 1 | — | 0.360 | 0.028 | 0.010 | 0.040 |
| 7 | 58 | 37 | 4 | 1 | — | 0.590 | 0.017 | 0.010 | 0.040 |
| 8 | 46 | 48 | 4 | 2 | — | 0.480 | 0.042 | 0.020 | 0.040 |
| 9 | 56 | 39 | 3 | 2 | — | 0.580 | 0.034 | 0.020 | 0.030 |
| 10 | 57 | 35 | 3 | 5 | — | 0.618 | 0.081 | 0.050 | 0.030 |
| 11 | 53 | 30 | 3 | 14 | — | 0.670 | 0.209 | 0.140 | 0.030 |
| 12 | 52 | 28 | 3 | 17 | — | 0.690 | 0.246 | 0.170 | 0.030 |
| 13 | 51 | 25 | 3 | 21 | — | 0.720 | 0.292 | 0.210 | 0.030 |
| 14 | 51 | 18 | 10 | 21 | — | 0.720 | 0.292 | 0.210 | 0.100 |
| 15 | 52 | 5 | 3 | 40 | — | 0.920 | 0.435 | 0.400 | 0.030 |
| 16 | 50 | 4 | 4 | 42 | — | 0.920 | 0.457 | 0.420 | 0.040 |
| 17 | 63 | 19 | 4 | 14 | — | 0.768 | 0.182 | 0.140 | 0.040 |
| 18 | 54 | 32 | 1 | 13 | — | 0.670 | 0.194 | 0.130 | 0.010 |
| 19 | 53 | 30 | 10 | 7 | — | 0.600 | 0.117 | 0.070 | 0.100 |
| 20 | 40 | 38 | 12 | 10 | — | 0.500 | 0.200 | 0.100 | 0.120 |
| 21 | 33 | 33 | — | — | 33 | 0.500 | 0.000 | 0.000 | 0.000 |

TABLE 2

| | Mobility | Vth | PBTS | NBTS | Carrier | W/E rate |
|---|---|---|---|---|---|---|
| No | cm²/Vs | V | Δ V th | Δ V th | density/cm³ | nm/sec |
| 1 | 12 | 0.4 | 3.2 | −0.1 | 5.1E+16 | 4.7 |
| 2 | 15 | 0.7 | 1.8 | −1.2 | 2.5E+17 | 2.8 |
| 3 | 50 | −5.2 | 0.5 | −5.0 | 4.1E+19 | <0.1 |
| 4 | 6 | 0.3 | 3.2 | −0.9 | 2.5E+16 | 13.0 |
| 5 | 5 | 2.8 | 4.5 | −0.5 | 4.0E+14 | 15.0 |
| 6 | 10 | 1.8 | 1.8 | −0.4 | 3.5E+17 | 10.0 |
| 7 | 17 | 0.7 | 0.9 | −1.2 | 5.6E+17 | 2.6 |
| 8 | 20 | 0.9 | 1.5 | −0.6 | 4.2E+17 | 3.0 |
| 9 | 21 | 0.8 | 1.2 | −1.0 | 3.5E+17 | 2.2 |
| 10 | 23 | 0.6 | 1.0 | −0.7 | 5.6E+17 | 1.0 |
| 11 | 26 | 0.3 | 0.7 | −0.2 | 2.5E+18 | <0.1 |
| 12 | 27 | 0.2 | 0.6 | −1.5 | 4.1E+18 | <0.1 |
| 13 | 28 | 0.1 | 0.6 | −2.0 | 4.0E+18 | <0.1 |
| 14 | 20 | 0.7 | 1.1 | −0.6 | 6.0E+17 | <0.1 |
| 15 | 29 | −3.6 | 0.5 | −3.4 | 8.5E+18 | <0.1 |
| 16 | 32 | −4.6 | 0.2 | −4.8 | 6.0E+19 | <0.1 |
| 17 | 27 | −0.8 | 0.6 | −2.2 | 5.2E+18 | <0.1 |
| 18 | 25 | −4.1 | 1.1 | −4.2 | 2.8E+19 | <0.1 |
| 19 | 11 | 2.6 | 3.4 | −0.6 | 7.0E+16 | <0.1 |
| 20 | 8 | 2.8 | 3.1 | 0.7 | 3.8E+15 | <0.1 |
| 21 | 8 | 3.6 | 6.3 | 0.2 | 5.7E+14 | 5.3 |

From the viewpoint of transistor characteristics, the mobility tends to increase as the content of In increases, and the threshold value voltages tends to shift to the negative side as the content of In or Sn increases. When the content of each of In and Sn is small and the content of Ti is large, the threshold value voltage increases, which tends to degrade PBTS but improve NBTS. Meanwhile, the content of each of In and Sn is large and the content of Ti is small, the threshold value voltage is lowered, which tends to improve PBTS but degrades NBTS.

As compared with the In—Ga—Zn—O oxide semiconductor thin film according to the sample 21, the In—Ti—Zn—O oxide semiconductor thin films according to the samples 1 to 5 each have a low threshold value voltage. The samples having a high mobility had a low threshold value voltage.

The mobility was not less than 10 cm²/Vs in the samples 1 to 3 while the mobility was lower than the mobility of the sample 21 (In—Ga—Zn—O) in the samples 4 and 5.

Meanwhile, in accordance with each of the In—Sn—Ti—Zn—O oxide semiconductor thin films according to the samples 6 to 20, since the mobility was higher than that of the sample 21 (In—Ga—Zn—O) and the threshold value voltage was lower than that of the sample 21 (In—Ga—Zn—O), also PBTS/NBTS characteristics were favorable.

Note that in accordance with the In—Sn—Ti—Zn—O oxide semiconductor thin film according to the sample 20, whose content of Ti is relatively high, the mobility was low as compared with those of the samples 6 to 19 and the degradation of PBTS was large.

That is, in accordance with the In—Sn—Ti—Zn—O oxide semiconductor thin films in which the atomic ratio 1 is not less than 0.36 and not more than 0.92, the atomic ratio 2 is not less than 0.02 and not more than 0.46, the atomic ratio 3 is not less than 0.01 and not more than 0.42, and the atomic ratio 4 is not less than 0.01 and not more than 0.10, transistor characteristics having a mobility of not less than 10 cm²/Vs, which is higher than that of the In—Ga—Zn—O, can be achieved.

Further, the In—Sn—Ti—Zn—O oxide semiconductor thin films according to the samples 8 to 14 in which the atomic ratio 1 is not less than 0.48 and not more than 0.72, the atomic ratio 2 is not less than 0.03 and not more than 0.29, the atomic ratio 3 is not less than 0.02 and not more than 0.21, and the atomic ratio 4 is not less than 0.03 and not more than 0.10, transistor characteristics with excellent reliability and less fluctuation in threshold value voltage, such as a mobility of not less than 20 cm²/Vs, PBTS characteristics of not less than 0 V and not more than 2 V, and NBTS characteristics of not less than −2 V and not more than 0 V, can be achieved.

The In—Sn—Ti—Zn—O oxide semiconductor thin films according to the samples 8 to 14 were confirmed to be amorphous even after annealing. In the case where the oxide semiconductor film has an amorphous structure, it is unnecessary to control the crystal size and grain boundaries. Therefore, a thin film transistor including an oxide semiconductor film having an amorphous structure as an active layer has an advantage that the variation in mobility is small and enlargement can be easily performed.

Whether or not the active layer is amorphous can be evaluated by an X-ray diffraction pattern, an electron beam diffraction pattern, or the like.

Further, in accordance with the In—Sn—Ti—Zn—O oxide semiconductor thin films according to the samples 7 to 19, the etching rate can be suppressed to not more than 3 nm/sec. As a result, it is unnecessary to provide an etching stopper layer for protecting an active layer including the oxide semiconductor thin film from an etching solution for forming a source/drain electrode, and it is possible to produce a thin film transistor.

Although an embodiment of the present invention has been described above, it goes without saying that the present invention is not limited to only the above-mentioned embodiment, and various modifications can be made.

For example, although a so-called bottom gate (inverted staggered) transistor has been described as an example in the above-mentioned embodiment, the present invention is applicable to a top gate (staggered) thin film transistor.

Further, the above-mentioned thin film transistor can be used as a TFT for an active matrix display panel such as a liquid crystal display and an organic EL display. In addition thereto, the above-mentioned transistor can be used as a transistor device of various semiconductor apparatuses and electric apparatuses.

### REFERENCE SIGNS LIST

10 substrate
11 gate electrode
12 gate insulation film
13 active layer
14S source electrode
14D drain electrode
15 protective film

1. An oxide semiconductor thin film, comprising:
an oxide semiconductor containing In, Zn, Ti, and Sn,
an atomic ratio of (In+Sn)/(In+Zn+Ti+Sn) being not less than 0.36 and not more than 0.92,
an atomic ratio of Sn/(In+Sn) being not less than 0.02 and not more than 0.46,
an atomic ratio of Sn/(In+Zn+Ti+Sn) being not less than 0.01 and not more than 0.42,
an atomic ratio of Ti/(In+Zn+Ti+Sn) being not less than 0.01 and not more than 0.10,
a carrier concentration being not less than 7.0×10¹⁶/cm³ and not more than 6.0×10¹⁹/cm³.

2. The oxide semiconductor thin film according to claim 1, wherein
the atomic ratio of (In+Sn)/(In+Zn+Ti+Sn) is not less than 0.48 and not more than 0.72,
the atomic ratio of Sn/(In+Sn) is not less than 0.03 and not more than 0.29,
the atomic ratio of Sn/(In+Zn+Ti+Sn) is not less than 0.02 and not more than 0.21,
the atomic ratio of Ti/(In+Zn+Ti+Sn) is not less than 0.03 and not more than 0.10, and
the carrier concentration being not less than 3.5×10¹⁷/cm³ and not more than 4.1×10¹⁹/cm³.

3. The oxide semiconductor thin film according to claim 1, wherein a mobility is not less than 10 cm²/Vs.

4. The oxide semiconductor thin film according to claim 2, wherein a mobility is not less than 20 cm²/Vs.

5. The oxide semiconductor thin film according to claim 1, wherein the oxide semiconductor thin film is resistant to an acidic etching solution.

6. A thin film transistor, comprising:
an active layer that includes the oxide semiconductor thin film according to claim 1,
a mobility being not less than 10 cm²/Vs.

7. A thin film transistor, comprising:
an active layer that includes the oxide semiconductor thin film according to claim 2,
a mobility being not less than 20 cm²/Vs.

8. The thin film transistor according to claim 7, wherein
an amount of change in threshold value before and after execution of a test in which a gate voltage of +30 V is applied at a temperature of 60° C. for 60 minutes is not less than 0 V and not more than 2 V.

9. The thin film transistor according to claim 7, wherein an amount of change in threshold value before and after execution of a test in which a gate voltage of −30 V is applied at a temperature of 60° C. for 60 minutes is not less than 0 V and not more than 2 V.

10. A method of producing a thin film transistor that includes an active layer including the oxide semiconductor thin film according to claim 1, comprising:
forming a gate insulation film on a gate electrode;
forming the active layer on the gate insulation film by a sputtering method;
forming a metal layer having the active layer as a base film; and
patterning the metal layer by a wet etching method to form a source electrode and a drain electrode.

11. A sputtering target for forming the oxide semiconductor thin film according to claim 1.
